(19) United States
(12) Patent Application Publication
(10) Pub. No.: US 2026/0344133 A1
(43) Pub. Date: Oct. 29, 2026

(54) LED LIGHT-EMITTING UNIT, LED CHIP, AND LIGHT-EMITTING DEVICE

(71) Applicant: Xiamen Changelight Co. Ltd., Xiamen (CN)

(72) Inventors: Shuaicheng CHEN, Xiamen (CN); Deyou YANG, Xiamen (CN); Lingna YE, Xiamen (CN); Xingen WU, Xiamen (CN); Yunrui FEI, Xiamen (CN); Jiahong ZHANG, Xiamen (CN); Jian HE, Xiamen (CN)

(73) Assignee: Xiamen Changelight Co. Ltd., Xiamen (CN)

(21) Appl. No.: 19/435,727

(22) Filed: Dec. 29, 2025

Related U.S. Application Data
(63) Continuation of application No. PCT/CN2025/105600, filed on Jun. 30, 2025.
(63) Continuation of application No. PCT/CN2025/105620, filed on Jun. 30, 2025.

(30) Foreign Application Priority Data
Mar. 7, 2025 (CN) 202510270263.2
Mar. 7, 2025 (CN) 202510270268.5
Mar. 7, 2025 (CN) 202520395461.7
Mar. 7, 2025 (CN) 202520395462.1

(51) Int. Cl. H10H 20/856; H10H 20/01; H10H 20/815; H10H 20/816; H10H 20/821; H10H 20/831; H10H 20/841; H10H 20/855; H10H 29/14

(52) U.S. Cl. CPC H10H 20/856; H10H 20/021; H10H 20/032; H10H 20/0363; H10H 20/815; H10H 20/8162; H10H 20/821; H10H 20/8312; H10H 20/8314; H10H 20/841; H10H 20/855; H10H 29/14

(57) ABSTRACT

A LED light-emitting unit is provided. The LED light-emitting unit includes: a substrate and an epitaxial stack disposed on a surface of the substrate. A local region of the epitaxial stack is etched at least to the first conductivity-type semiconductor layer to define a recess and a light-emitting mesa. A transparent conductive layer is disposed on the light-emitting mesa and has a first opening exposing a portion of the second conductivity-type semiconductor layer. A first insulating layer is disposed on a surface of the transparent conductive layer opposite to the epitaxial stack. A first electrode extends through the first opening to contact a top surface of the first insulating layer.

### CROSS-REFERENCE TO RELATED APPLICATIONS

This application is a continuation of International Patent Application No. PCT/CN2025/105600, filed on Jun. 30, 2025, which claims priority to Chinese Patent Applications No. CN202510270268.5 and CN202520395462.1, both filed on Mar. 7, 2025, and International Patent Application No. PCT/CN2025/105620, filed on Jun. 30, 2025, which claims priority to Chinese Patent Applications No. CN202510270263.2 and CN202520395461.7, both filed on Mar. 7, 2025, the entire contents of which are incorporated herein by reference for all purposes.

### BACKGROUND

Light-emitting diodes (LEDs) have advantages such as high efficiency, long service life, small size, and low power consumption, and are widely used in indoor and outdoor white-light illumination, display panels, backlight sources, and other applications. A LED chip functions to convert electrical energy into light energy, and typically includes an epitaxial wafer and an N-type electrode and a P-type electrode respectively disposed on the epitaxial wafer. The epitaxial wafer includes a P-type semiconductor layer, an N-type semiconductor layer, and an active layer disposed between the N-type semiconductor layer and the P-type semiconductor layer. When current flows through the LED chip, holes in the P-type semiconductor layer and electrons in the N-type semiconductor layer migrate toward the active layer and recombine therein, thereby causing the LED chip to emit light.

As the LED application market—particularly display applications—continues to expand, higher requirements have been imposed by LED packaging manufacturers on the light extraction efficiency and reliability of LED chips in order to ensure application performance. At present, although the internal quantum efficiency of most LED chips has approached approximately 99%, their light extraction efficiency remains generally low. The primary reasons include: (1) severe total internal reflection occurring inside the LED chip, which results in only a small portion of the light generated in the light-emitting layer being extracted; and (2) current crowding effects, which lead to reduced luminous efficiency of the LED chip.

With respect to reliability issues of LED chips, the primary factors include: (1) a relatively large number of functional dielectric layers disposed beneath a P-electrode pad region, such as a current blocking layer (also commonly referred to in the art as a CB layer) and a transparent conductive layer (also commonly referred to as an ITO layer). Such a structure increases the risk that the functional dielectric layers at the contact region may be damaged or cracked during soldering, thereby adversely affecting the reliability of the LED chip; and (2) during actual operation, moisture ingress may cause micro short-circuits under reverse-bias conditions, ultimately leading to burnout or failure of the LED chip, which significantly degrades reliability in practical applications and limits broader use. Accordingly, how to improve light extraction efficiency and reliability of LED chips without degrading optoelectronic performance has become an urgent technical problem to be addressed.

### SUMMARY

The present disclosure relates to the technical field of semiconductor device manufacturing, and more specifically, to a LED light-emitting unit, a LED chip, and a light-emitting device.

According a first aspect of the present disclosure, one or more embodiments provide a LED light-emitting unit. The LED light-emitting unit includes: a substrate; an epitaxial stack disposed on a surface of the substrate, a transparent conductive layer, a first insulating layer, and a first electrode. The epitaxial stack disposed includes, in sequence along a first direction, a first conductivity-type semiconductor layer, an active region, and a second conductivity-type semiconductor layer. A local region of the epitaxial stack is etched at least to the first conductivity-type semiconductor layer to define a recess and a light-emitting mesa. The first direction is perpendicular to the surface of the substrate and extends from the substrate toward the epitaxial stack. The transparent conductive layer is disposed on the light-emitting mesa and includes a first opening exposing a portion of the second conductivity-type semiconductor layer. The first insulating layer is disposed on a surface of the transparent conductive layer opposite to the epitaxial stack. The first electrode extends through the first opening to contact a top surface of the first insulating layer.

According to a second aspect of the present disclosure, one or more embodiments provide a LED chip. The LED chip includes a plurality of LED light-emitting units isolated from one another by a plurality of trenches. The LED light-emitting unit includes: a substrate; an epitaxial stack disposed on a surface of the substrate, a transparent conductive layer, a first insulating layer, and a first electrode. The epitaxial stack disposed includes, in sequence along a first direction, a first conductivity-type semiconductor layer, an active region, and a second conductivity-type semiconductor layer. A local region of the epitaxial stack is etched at least to the first conductivity-type semiconductor layer to define a recess and a light-emitting mesa. The first direction is perpendicular to the surface of the substrate and extends from the substrate toward the epitaxial stack. The transparent conductive layer is disposed on the light-emitting mesa and includes a first opening exposing a portion of the second conductivity-type semiconductor layer. A first insulating layer is disposed on a surface of the transparent conductive layer opposite to the epitaxial stack. The first electrode extends through the first opening to contact a top surface of the first insulating layer.

According to a third aspect of the present disclosure, one or more embodiments provide a light-emitting device or a lighting device. The light-emitting device or the lighting device includes a light-emitting diode employing the LED chip according to the second aspect of the present disclosure.

### BRIEF DESCRIPTION OF THE DRAWINGS

In order to more clearly illustrate the technical solutions of the embodiments of the present disclosure or the prior art, the drawings required in the description of the embodiments or the prior art are briefly described below. The drawings described below are merely embodiments of the present disclosure, and a person of ordinary skill in the art may obtain other drawings based on these drawings.

FIG. 1 is a schematic cross-sectional structural view of a LED chip provided according to one or more embodiments of the present disclosure.

FIG. 2 is a schematic cross-sectional structural view corresponding to a step of providing a substrate according to one or more embodiments of the present disclosure.

FIG. 3 is a schematic cross-sectional structural view corresponding to a step of growing an epitaxial stack according to one or more embodiments of the present disclosure.

FIG. 4 is a schematic cross-sectional structural view corresponding to a step of performing deep etching on the epitaxial stack according to one or more embodiments of the present disclosure.

FIG. 5 is a schematic cross-sectional structural view corresponding to a step of forming a recess and a light-emitting mesa according to one or more embodiments of the present disclosure.

FIG. 6 is a schematic cross-sectional structural view corresponding to a step of manufacturing a transparent conductive layer according to one or more embodiments of the present disclosure.

FIG. 7 is a schematic cross-sectional structural view corresponding to a step of depositing a transparent dielectric layer according to one or more embodiments of the present disclosure.

FIG. 8 is a schematic cross-sectional structural view corresponding to a step of manufacturing the second electrode and the first electrode according to one or more embodiments of the present disclosure.

FIG. 9 is a schematic cross-sectional structural view corresponding to a step of manufacturing a second insulating layer according to one or more embodiments of the present disclosure.

FIG. 10 is a schematic cross-sectional structural view corresponding to a step of performing dicing along the trenches according to one or more embodiments of the present disclosure.

FIG. 11 is a schematic cross-sectional structural view of a LED chip provided according to one or more embodiments of the present disclosure.

FIG. 12A is a schematic cross-sectional structural view of a LED chip provided according to one or more embodiments of the present disclosure.

FIG. 12B is a schematic cross-sectional structural view of a LED chip provided according to one or more embodiments of the present disclosure.

FIG. 13 is a schematic cross-sectional structural view of a LED chip provided according to one or more embodiments of the present disclosure.

FIG. 14 is a schematic cross-sectional structural view of a LED chip provided according to one or more embodiments of the present disclosure.

FIG. 15 is a schematic cross-sectional structural view of a LED chip provided according to one or more embodiments of the present disclosure.

FIG. 16 is a schematic cross-sectional structural view of a LED chip provided according to one or more embodiments of the present disclosure.

FIG. 17 is a schematic cross-sectional structural view of a LED chip provided according to one or more embodiments of the present disclosure.

FIG. 18 is a schematic cross-sectional structural view corresponding to a step of providing a substrate according to one or more embodiments of the present disclosure.

FIG. 19 is a schematic cross-sectional structural view corresponding to a step of growing an epitaxial stack according to one or more embodiments of the present disclosure.

FIG. 20 is a schematic cross-sectional structural view corresponding to a step of performing deep etching on the epitaxial stack according to one or more embodiments of the present disclosure.

FIG. 21 is a schematic cross-sectional structural view corresponding to a step of forming a recess and a light-emitting mesa according to one or more embodiments of the present disclosure.

FIG. 22 is a schematic cross-sectional structural view corresponding to a step of manufacturing a transparent conductive layer according to one or more embodiments of the present disclosure.

FIG. 23 is a schematic cross-sectional structural view corresponding to a step of depositing a transparent dielectric layer according to one or more embodiments of the present disclosure.

FIG. 24 is a schematic cross-sectional structural view corresponding to a step of forming the first insulating layer according to one or more embodiments of the present disclosure.

FIG. 25 is a schematic cross-sectional structural view corresponding to a step of manufacturing the second electrode and the first electrode according to one or more embodiments of the present disclosure.

FIG. 26 is a schematic cross-sectional structural view corresponding to a step of manufacturing a second insulating layer according to one or more embodiments of the present disclosure.

FIG. 27 is a schematic cross-sectional structural view corresponding to a step of performing dicing along the trenches according to one or more embodiments of the present disclosure.

FIG. 28 is a schematic cross-sectional structural view of a LED chip provided according to one or more embodiments of the present disclosure.

FIG. 29A is a schematic cross-sectional structural view of a LED chip provided according to one or more embodiments of the present disclosure.

FIG. 29B is a schematic cross-sectional structural view of a LED chip provided according to one or more embodiments of the present disclosure.

FIG. 30 is a schematic cross-sectional structural view of a LED chip provided according to one or more embodiments of the present disclosure.

FIG. 31 is a schematic cross-sectional structural view of a LED chip provided according to one or more embodiments of the present disclosure.

FIG. 32 is a schematic cross-sectional structural view of a LED chip provided according to one or more embodiments of the present disclosure.

FIG. 33 is a schematic cross-sectional structural view of a LED chip provided according to one or more embodiments of the present disclosure.

FIG. 34 is a schematic cross-sectional structural view of a LED chip provided according to one or more embodiments of the present disclosure.

### DETAILED DESCRIPTION

To make the content of the present disclosure clearer, the content of the present disclosure is further explained below in conjunction with the accompanying drawings. The scope of the present disclosure is not limited to the specific embodiments. Based on the embodiments of the present disclosure, all other embodiments obtained by those of ordinary skill in the art shall fall within the scope of protection of the present disclosure.

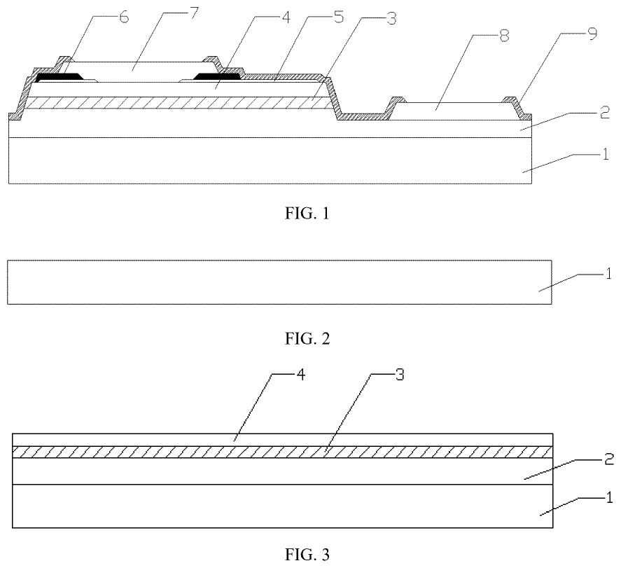

FIG. 1 is a schematic cross-sectional structural diagram of a LED chip provided by one or more embodiments of the present disclosure. The LED chip includes a substrate 1 and a plurality of LED light-emitting units disposed on the surface of the substrate 1 and isolated from each other by trenches. As shown in FIG. 1, the LED light-emitting unit includes:

An epitaxial stack disposed on the surface of the substrate 1. The epitaxial stack includes, stacked in sequence along a first direction, a first conductivity-type semiconductor layer 2, an active region 3, and a second conductivity-type semiconductor layer 4. A local region of the epitaxial stack is etched at least to the first conductivity-type semiconductor layer 2 to define a recess 10 and a light-emitting mesa 11 (refer to FIG. 5). The first direction is perpendicular to the surface of the substrate 1 and extends from the substrate 1 toward the epitaxial stack.

A transparent conductive layer 5 is disposed on the light-emitting mesa 11 and has a first opening 5.1 exposing a portion of the second conductivity-type semiconductor layer 4.

A first insulating layer 6 is disposed on a surface of the transparent conductive layer 5 opposite to the epitaxial stack.

A first electrode 7 extends through the first opening 5.1 to contact a top surface of the first insulating layer 6.

A second electrode 8 is disposed on a bottom surface of the recess 10 and spaced apart from the light-emitting mesa 11.

A second insulating layer 9 is disposed on a surface of the epitaxial stack and exposes at least portions of the second electrode 8 and the first electrode 7. Further, the second insulating layer 9 covers the light-emitting mesa and the recess and exposes portions of the surfaces of the second electrode 8 and the first electrode 7.

The type of substrate 1 is not limited in the LED chip of this embodiment. For example, the substrate 1 may be, but is not limited to, a sapphire substrate 1, a silicon substrate 1, etc. Additionally, the types of the first conductivity-type semiconductor layer 2, the active region 3, and the second conductivity-type semiconductor layer 4 of the epitaxial stack are also not limited in the LED chip of this embodiment. In embodiments of the present disclosure, the first conductivity-type semiconductor layer 2 may be an N-type semiconductor layer, and correspondingly, the second conductivity-type semiconductor layer 4 may be a P-type semiconductor layer. For instance, the first conductivity-type semiconductor layer 2 may be, but is not limited to, an N-type gallium nitride layer, and correspondingly, the second conductivity-type semiconductor layer 4 may be, but is not limited to, a P-type gallium nitride layer.

In order to highlight the technical features of the present disclosure, the drawing only schematically shows one epitaxial stack unit. In practical product applications, it may include thousands or tens of thousands of epitaxial stack units, depending on the application of the LED chip product, which is not limited herein.

In one or more embodiments of the present disclosure, the first insulating layer 6 exposes a portion of the transparent conductive layer 5 to form a step, and the first electrode 7 extends to the surface of the first insulating layer 6 via the step.

In one or more embodiments of the present disclosure, a projection of the first electrode 7 on the transparent conductive layer 5 and a projection of the first electrode 7 on the first insulating layer 6 have an overlapping region with an area Sₐ, and a projection area of the first electrode 7 on the transparent conductive layer 5 is S₁, such that 0<Sₐ≤S_{1/2}.

In one or more embodiments of the present disclosure, the step is disposed around an edge of the first opening 5.1.

In one or more embodiments of the present disclosure, the transparent conductive layer 5 covers at least 80% of the area of the light-emitting mesa 11 excluding the first opening 5.1. Further, an edge of the transparent conductive layer 5 is located inward from an edge of the second conductivity-type semiconductor layer 4, with a distance d between them. This distance d is not greater than 2.5 μm. In one or more embodiments of the present disclosure, the distance d is not greater than 1.5 μm, for example, 1 μm. By reducing the distance from the edge of the transparent conductive layer 5 to the edge of the second conductivity-type semiconductor layer 4, the area of the transparent conductive layer 5 is increased, thereby increasing the area of the light-emitting region and achieving further enhancement of the LED's brightness.

In one or more embodiments of the present disclosure, the second insulating layer 9 covers the light-emitting mesa and the recess while exposing a surface of the first conductivity-type semiconductor layer 2, and exposes portions of the surfaces of the second electrode 8 and the first electrode 7.

In one or more embodiments of the present disclosure, the first electrode 7 has a metal reflective layer.

In one or more embodiments of the present disclosure, a bottom layer of the first electrode 7 is the metal reflective layer.

In one or more embodiments of the present disclosure, the metal reflective layer includes one or more of Ag, Ni, Al, Rh, Pd, Ir, Ru, Mg, Zn, Pt, and Au.

In one or more embodiments of the present disclosure, the transparent conductive layer 5 includes a metal thin film or a metal oxide layer.

In one or more embodiments of the present disclosure, the metal thin film includes one or more of gold, silver, platinum, copper, aluminum, chromium, and palladium.

In one or more embodiments of the present disclosure, the metal oxide layer includes one or more of indium oxide, indium tin oxide, zirconium oxide, cadmium oxide, and titanium nitride.

In one or more embodiments of the present disclosure, the second insulating layer 9 includes, but is not limited to, one or more of silicon oxide and magnesium fluoride.

According to the LED chip provided by embodiments of the present disclosure, through the arrangement including: the epitaxial stack including the first conductivity-type semiconductor layer 2, the active region 3, and the second conductivity-type semiconductor layer 4 stacked in sequence along the first direction; the local region of the epitaxial stack being etched at least to the first conductivity-type semiconductor layer 2 to form the recess 10 and the light-emitting mesa 11; the transparent conductive layer 5 disposed on the light-emitting mesa 11 and having the first opening 5.1 exposing a portion of the second conductivity-type semiconductor layer 4; the first insulating layer 6 being formed on the surface of the transparent conductive layer 5 opposite to the epitaxial stack; the second electrode 8 disposed on a bottom surface of the recess 10 and spaced apart from the light-emitting mesa 11; the first electrode 7 extending through the first opening 5.1 to contact a top surface of the first insulating layer 6; and the second insulating layer 9 disposed on the surface of the epitaxial stack and exposing at least portions of the second electrode 8 and the first electrode 7. Based on the above arrangement, a composite region is formed among the first insulating layer 6, the transparent conductive layer 5, the second insulating layer 9, and the first electrode 7. Thereby, an ODR structure is formed through the inter-structural relationships among the transparent conductive layer 5, the first insulating layer 6, the first electrode 7, and the second insulating layer 9. Light can undergo total internal reflection in this composite region, so that light corresponding to the composite region under the first electrode 7 is reflected and extracted from the upper surface of the LED chip, thereby effectively enhancing light extraction efficiency. Simultaneously, based on the above arrangement, the second insulating layer 9 is disposed on the surface of the epitaxial stack and on portions of the surfaces of the second electrode 8/first electrode 7. At the edge of the first electrode 7, the first insulating layer 6 and the second insulating layer 9, extending in different directions, can form a connecting structure with an angle. This can effectively alleviate the diffusion of tensile stress generated in the LED chip under special environments (such as high temperature and high pressure), thereby reducing the risk of functional dielectric layers (such as the transparent conductive layer 5, insulating layers, etc.) being cracked or fractured during bonding, which would affect the reliability of the LED chip. Moreover, the dual protection provided by the first insulating layer 6 and the second insulating layer 9 enhances the moisture resistance capability of the LED chip.

By arranging the first insulating layer 6 to expose a portion of the transparent conductive layer 5 to form a step, and the first electrode 7 extending to the surface of the first insulating layer 6 via the step, the electrode contact area can be increased through the step, thereby dispersing stress and reducing the risk of local failure.

By arranging that the projection of the first electrode 7 on the transparent conductive layer 5 and the projection of the first electrode 7 on the first insulating layer 6 have an overlapping region with an area Sₐ, and the projection area of the first electrode 7 on the transparent conductive layer 5 is S₁, such that 0<Sₐ≤S_{1/2}. Thus, while ensuring the contact area between the first electrode 7 and the transparent conductive layer 5 to reduce contact resistance, the size of the composite region area is ensured to improve the ODR reflection effect.

One or more embodiments of the present disclosure provide a method for manufacturing a LED chip, used for manufacturing the LED chip according to an embodiment of the present disclosure. The manufacturing method includes the following steps:
S01A: As shown in FIG. 2, provide a substrate 1.

The type of substrate 1 is not limited in the LED chip of this embodiment. For example, the substrate 1 may be, but is not limited to, a sapphire substrate, a silicon substrate.
S02A: As shown in FIG. 3, grow an epitaxial stack. The epitaxial stack includes, stacked in sequence along a first direction, a first conductivity-type semiconductor layer 2, an active region 3, and a second conductivity-type semiconductor layer 4. The first direction is perpendicular to the surface of the substrate 1 and extends from the substrate 1 toward the epitaxial stack.

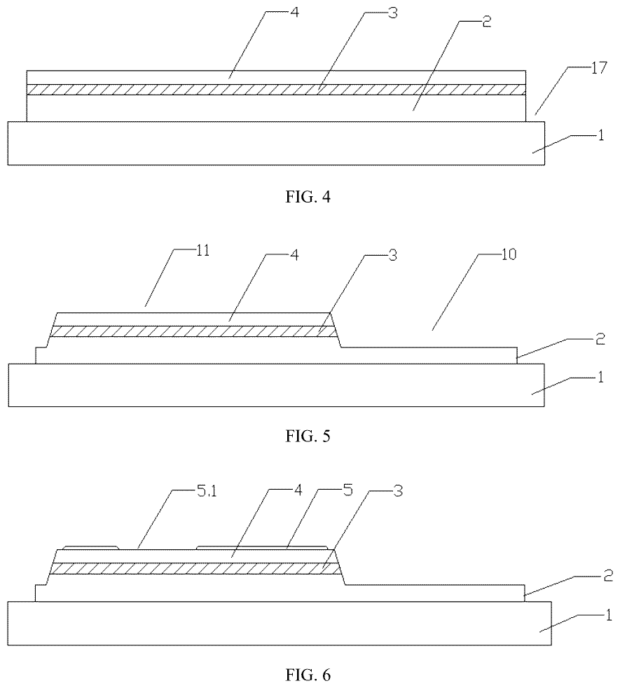

In one or more embodiments of the present disclosure, the first conductivity-type semiconductor layer 2 may be an N-type semiconductor layer, and correspondingly, the second conductivity-type semiconductor layer 4 may be a P-type semiconductor layer. For instance, the first conductivity-type semiconductor layer 2 may be, but is not limited to, an N-type gallium nitride layer, and correspondingly, the second conductivity-type semiconductor layer 4 may be, but is not limited to, a P-type gallium nitride layer.
S03A: As shown in FIG. 4, perform deep etching on the epitaxial stack to expose the surface of the substrate 1, forming a plurality of mutually independent epitaxial stack units separated by trenches.

In one or more embodiments of the present disclosure, performing deep etching on the epitaxial stack to expose the surface of substrate 1 and forming a plurality of epitaxial stack units arranged spaced apart by trenches includes: using an Inductively Coupled Plasma (ICP) process with etching gases including Cl₂, Ar, and O₂. However, this is not limiting in the present disclosure and depends on the specific situation.

In order to highlight the technical features of the present disclosure, the drawing only schematically shows one epitaxial stack unit. In practical product applications, it may include thousands or tens of thousands of epitaxial stack units, depending on the application of the LED chip product, which is not limited herein.
S04A: As shown in FIG. 5, etch each of the epitaxial stack units to partially expose the first conductivity-type semiconductor layer 2, thereby forming a recess 10 and a light-emitting mesa 11.

In one or more embodiments of the present disclosure, etching the epitaxial stack to form the recess 10 and the light-emitting mesa 11 includes: using an Inductively Coupled Plasma (ICP) process with etching gases including Cl₂, Ar, and O₂. However, this is not limiting in the present disclosure and depends on the specific situation.

In one or more embodiments of the present disclosure, the recess is disposed at a first end of the LED light-emitting unit.

In one or more embodiments of the present disclosure, the exposed surface of the first conductivity-type semiconductor layer is disposed surrounding the periphery of the light-emitting mesa 11.
S05A: As shown in FIG. 6, manufacture a transparent conductive layer 5 on the light-emitting mesa 11, wherein the transparent conductive layer 5 has a first opening 5.1 exposing a portion of the second conductivity-type semiconductor layer 4.

In one or more embodiments of the present disclosure, the transparent conductive layer 5 covers at least 80% of the area of the light-emitting mesa 11 excluding the first opening 5.1. Further, an edge of the transparent conductive layer 5 is located inward from an edge of the second conductivity-type semiconductor layer 4, with a distance d between them. This distance d is not greater than 2.5 μm. In one or more embodiments of the present disclosure, the distance d is not greater than 1.5 μm, for example, 1 μm. By reducing the distance from the edge of the transparent conductive layer 5 to the edge of the second conductivity-type semiconductor layer 4, the area of the transparent conductive layer 5 is increased, thereby increasing the area of the light-emitting region and achieving further enhancement of the LED's brightness.

In one or more embodiments of the present disclosure, the transparent conductive layer 5 includes a metal thin film or a metal oxide layer.

In one or more embodiments of the present disclosure, the metal thin film includes one or more of gold, silver, platinum, copper, aluminum, chromium, and palladium.

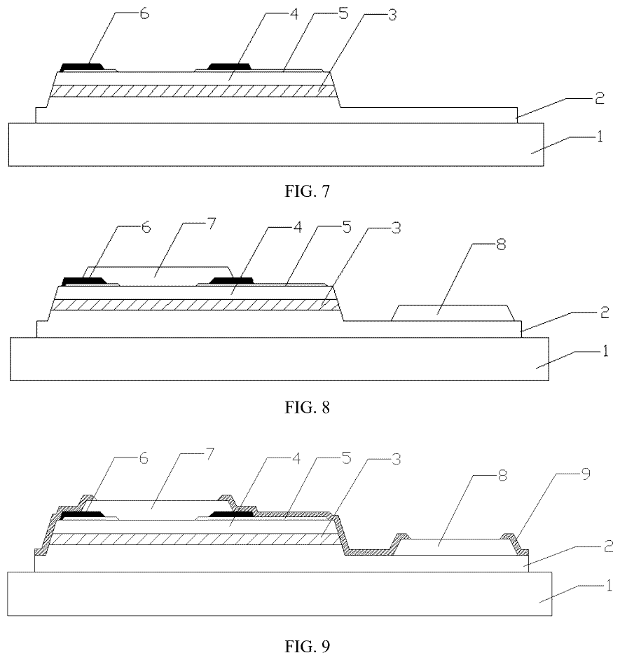

In one or more embodiments of the present disclosure, the metal oxide layer includes one or more of indium oxide, indium tin oxide, zirconium oxide, cadmium oxide, and titanium nitride.
S06A: Deposit a transparent dielectric layer covering exposed surfaces of each epitaxial stack unit. Subsequently, apply a photoresist on the surface of the transparent dielectric layer and use a mask and etching process to obtain the transparent dielectric layer located on the surface of the transparent conductive layer 5, thereby forming the first insulating layer 6 as shown in FIG. 7.

In one or more embodiments of the present disclosure, the transparent dielectric layer includes one or more of materials such as silicon oxide, titanium oxide, silicon nitride, aluminum oxide, magnesium fluoride, spin-on glass (SOG), polymer, etc.

In one or more embodiments of the present disclosure, the first insulating layer 6 exposes a portion of the transparent conductive layer 5 to form a step.

In one or more embodiments of the present disclosure, the step is disposed around an edge of the first opening 5.1.
S07A: As shown in FIG. 8, manufacture the second electrode 8 and the first electrode 7.

The second electrode 8 is disposed on a bottom surface of the recess 10 and spaced apart from the light-emitting mesa 11.

The first electrode 7 extends through the first opening 5.1 to contact a top surface of the first insulating layer 6. Further, the first electrode 7 extends to the surface of the first insulating layer 6 via the step.

In one or more embodiments of the present disclosure, a projection of the first electrode 7 on the transparent conductive layer 5 and a projection of the first electrode 7 on the first insulating layer 6 have an overlapping region with an area Sₐ, and a projection area of the first electrode 7 on the transparent conductive layer 5 is S₁, such that 0<Sₐ≤S_{1/2}.

In one or more embodiments of the present disclosure, the second electrode 8 and the first electrode 7 may be metal electrodes, i.e., made of metal materials, such as at least one of nickel, gold, chromium, titanium, platinum, palladium, rhodium, iridium, aluminum, tin, indium, tantalum, copper, cobalt, iron, ruthenium, zirconium, tungsten, and molybdenum, or at least one of alloys or stacks of the above materials.

In one or more embodiments of the present disclosure, the first electrode 7 has a metal reflective layer.

In one or more embodiments of the present disclosure, a bottom layer of the first electrode 7 is the metal reflective layer. Further, the metal reflective layer includes one or more of Ag, Ni, Al, Rh, Pd, Ir, Ru, Mg, Zn, Pt, and Au.
S08A: As shown in FIG. 9, manufacture a second insulating layer 9. It is disposed on a surface of the epitaxial stack and exposes at least portions of the second electrode 8 and the first electrode 7. Further, the second insulating layer 9 covers the light-emitting mesa 11 and the recess 10 while exposing a surface of the first conductivity-type semiconductor layer 2, and exposes portions of the surfaces of the second electrode 8 and the first electrode 7.

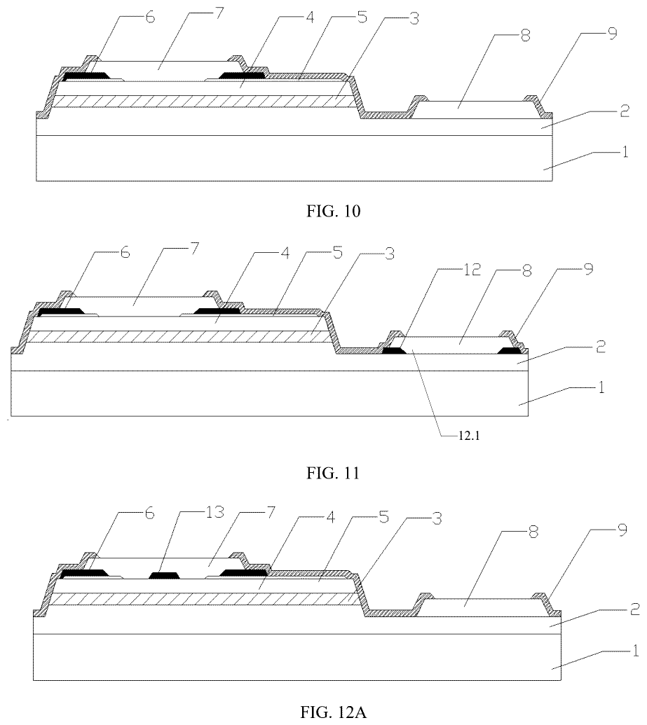

In one or more embodiments of the present disclosure, the second insulating layer 9 includes, but is not limited to, one or more of silicon oxide and magnesium fluoride.
S09A: Perform dicing along the trenches to finally obtain a plurality of LED light-emitting units as shown in FIG. 10.

FIG. 11 is a schematic cross-sectional structural diagram of a LED chip provided by one or more embodiments of the present disclosure. Compared to the LED chip shown in FIG. 1, the main difference of the LED chip in this Embodiment 3 is that a third insulating layer 12 is further disposed on the surface of the recess 10, and the third insulating layer 12 has a second opening 12.1 exposing a portion of the first conductivity-type semiconductor layer 2. The second electrode 8 is disposed on a surface of the third insulating layer 12 by being embedded in the second opening 12.1. Thereby, the stability of the second electrode 8 is further improved.

In one or more embodiments of the present disclosure, the first insulating layer 6 and the third insulating layer may be formed simultaneously by using photolithography to etch the transparent dielectric layer in step S06A.

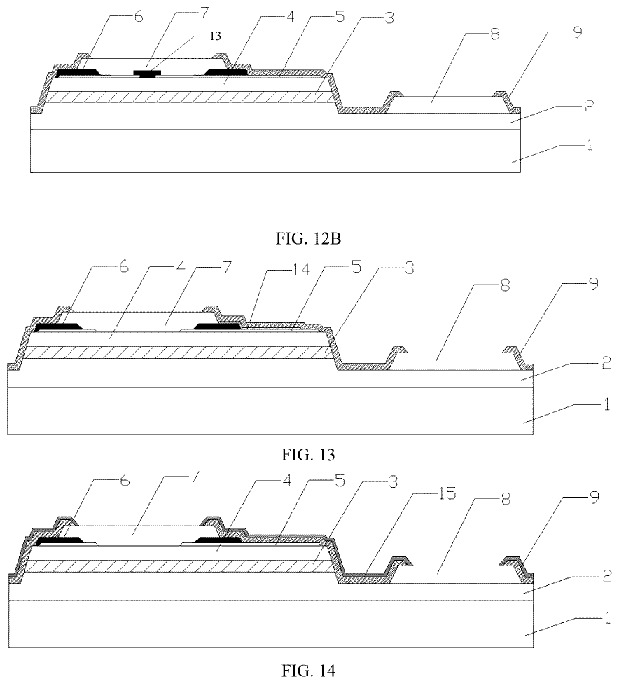

FIG. 12A is a schematic cross-sectional structural diagram of a LED chip provided by one or more embodiments of the present disclosure. Compared to the LED chip shown in FIG. 1, the main difference of this LED chip is that a current blocking layer 13 is disposed on the bottom surface of the first opening 5.1. Further, the current blocking layer 13 and the transparent conductive layer 5 form a spacing groove, and the first electrode 7 is embedded in the spacing groove to contact the second conductivity-type semiconductor layer 4. This improves current crowding, promotes lateral current spreading, and simultaneously, the inter-structural relationships among the first electrode 7 (metal reflector), the first insulating layer 6 (dielectric layer), the spacing groove, the current blocking layer 13 (dielectric layer), and the transparent conductive layer 5 (conductive layer) form another ODR structure, which is beneficial for increasing the area of the total reflection layer under the first electrode 7, further enhancing reflection efficiency.

In one or more embodiments of the present disclosure, the projection area of the current blocking layer 13 on the transparent conductive layer 5 is S₂, and the bottom surface area of the first opening 5.1 is S₃, such that 0<S₂≤S_{3/2}. Thus, while ensuring current blocking and total reflection effects, the contact area between the first electrode 7 and the second conductivity-type semiconductor layer 4 is ensured to improve the reliability of electrode wire bonding. The specific area of the current blocking layer 13 needs to meet the above requirements. The shape of the current blocking layer 13 may be trapezoidal, square, or rectangular.

In one or more embodiments of the present disclosure, the first insulating layer 6 and the current blocking layer 13 may be formed simultaneously by using photolithography to etch the transparent dielectric layer in step S06A.

FIG. 12B is a schematic cross-sectional structural diagram of a LED chip provided by one or more embodiments of the present disclosure. Compared to the LED chip shown in FIG. 1, the main difference of this LED chip is that it includes a current blocking layer 13. The current blocking layer 13 extends through the first opening 5.1 to contact a top surface of the first insulating layer 6. The current blocking layer 13 and the first insulating layer 6 are spaced apart by a spacing groove, and the spacing groove between the current blocking layer 13 and the first insulating layer 6 exposes a portion of the transparent conductive layer 5 surrounding the periphery of the current blocking layer 13. The first electrode 7 covers the current blocking layer 13 by being embedded in the spacing groove between the current blocking layer 13 and the first insulating layer 6, and extends to the surface of the first insulating layer 6, so that it has a composite region with the transparent conductive layer 5 and the first insulating layer 6 along the first direction. With this arrangement, an ODR structure is formed through the inter-structural relationships among the first electrode 7 (metal reflector), the first insulating layer 6 (dielectric layer), the spacing groove, the current blocking layer 13 (dielectric layer), and the transparent conductive layer 5 (conductive layer). Light can undergo total internal reflection in the composite region of the first electrode 7 with the transparent conductive layer 5 and the first insulating layer 6, so that light corresponding to this composite region under the first electrode 7 is reflected and extracted from the upper surface of the LED chip, thereby effectively enhancing light extraction efficiency. Simultaneously, the current blocking layer 13 disposed directly below the first electrode 7 can effectively prevent current crowding caused by the current injected from the first electrode 7 (P-type electrode) of the LED chip concentrating directly under the electrode.

In one or more embodiments of the present disclosure, the area of the composite region of the first electrode 7 with the transparent conductive layer 5 and the first insulating layer 6 is S₁₀ and the area of the bottom surface of the first opening 5.1 is S₃, such that 0.5*S₁₀≤S₃≤3*S₁₀. Thus, while ensuring the contact area between the first electrode 7 and the transparent conductive layer 5 to reduce contact resistance, the area size of the composite region of the first electrode 7 with the transparent conductive layer 5 and the first insulating layer 6 is ensured to improve the ODR reflection effect.

In one or more embodiments of the present disclosure, the first insulating layer 6 and the current blocking layer 13 may be formed simultaneously by using photolithography to etch the transparent dielectric layer in step S06A.

FIG. 13 is a schematic cross-sectional structural diagram of a LED chip provided by one or more embodiments of the present disclosure. Compared to the LED chip shown in FIG. 1, the main difference of this LED chip is that: the second electrode 8 includes a second electrode pad disposed at a first end of the LED light-emitting unit. The first opening 5.1 is formed at a second end of the LED light-emitting unit. The first electrode 7 includes a first electrode pad and at least one electrode extension strip 14 connected to the first electrode pad. The first electrode pad extends through the first opening 5.1 to contact a top surface of the first insulating layer 6, and the electrode extension strip 14 extends from the first electrode pad towards the second end of the LED light-emitting unit. Thereby, current can be better guided and spread through the electrode extension strip 14, avoiding current crowding. The material, shape, and structure of the electrode extension strip 14 need to meet the requirements for electrode extension and guidance.

In one or more embodiments of the present disclosure, the second electrode 8 may also include an electrode extension strip connected to the second electrode pad and extending towards the first end.

In one or more embodiments of the present disclosure, at least a portion of the electrode extension strip 14 makes contact with the transparent conductive layer 5.

In one or more embodiments of the present disclosure, the electrode extension strip 14 has a forked structure, and the forked structure makes contact with the transparent conductive layer 5 by penetrating through the first insulating layer 6. Alternatively, the transparent conductive layer 5 has through-holes, and the electrode extension strip 14 has forked fingers, and the forked fingers are formed and held in the through-holes of the transparent conductive layer 5.

In one or more embodiments of the present disclosure, a combination of the embodiments shown in FIG. 13 and FIG. 12 may be used, which is not elaborated herein.

FIG. 14 is a schematic cross-sectional structural diagram of a LED chip provided by one or more embodiments of the present disclosure. Compared to the LED chip shown in FIG. 1, the main difference of this LED chip is that: the LED chip further includes a refractive-index matching layer 15 disposed on a surface of the second insulating layer 9 opposite to the epitaxial stack and forming a graded-index structure with the second insulating layer 9, further enhancing light extraction efficiency. In one or more embodiments of the present disclosure, a refractive index of the refractive-index matching layer 15 is not less than a refractive index of the second insulating layer 9. Furthermore, if the first insulating layer 6 or the second insulating layer 9 includes a layered structure composed of one or more of SiO₂ and MgF₂, then the refractive-index matching layer 15 may include a layered structure composed of one or more of TiO₂, Si₃N₄, and Al₂O₃. In one or more embodiments of the present disclosure, the second insulating layer 9 is a SiO₂ layer, and the refractive-index matching layer 15 is an Al₂O₃ layer. Benefiting from the excellent passivation properties of Al₂O₃, it can effectively cover dangling bonds and defect states on the SiO₂ surface, reducing non-radiative recombination of carriers at the surface. The reduction in non-radiative recombination directly improves the internal quantum efficiency (IQE), meaning more electrical energy is converted into light energy rather than heat.

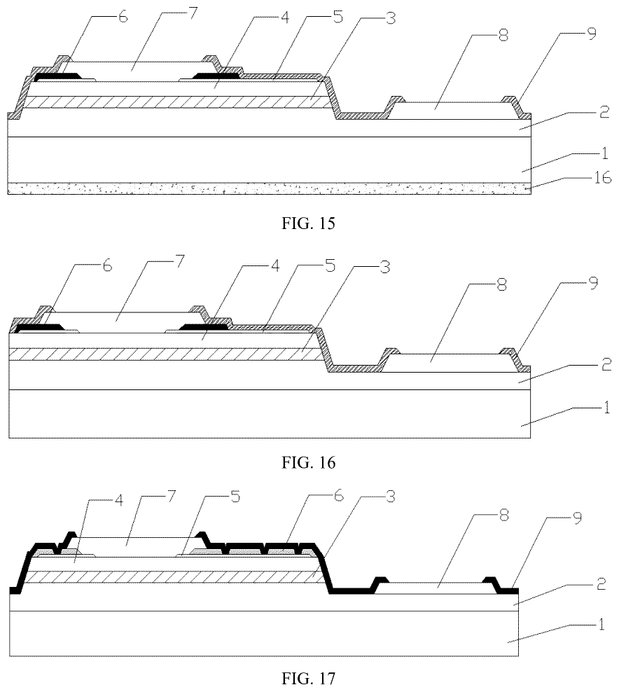

FIG. 15 is a schematic cross-sectional structural diagram of a LED chip provided by one or more embodiments of the present disclosure. Compared to the LED chip shown in FIG. 1, the main difference of this LED chip is that: a reflective layer 16 is further disposed on a surface of the substrate 1 opposite to the epitaxial stack. Further, the reflective layer 16 includes a distributed Bragg reflector (DBR) composed of alternating stacks of high-refractive-index material layers and low-refractive-index material layers. Alternatively, the reflective layer may also be a metal reflective layer. Its material needs to meet the requirements for a DBR/metal reflector.

FIG. 16 is a schematic cross-sectional structural diagram of a LED chip provided by one or more embodiments of the present disclosure. Compared to the LED chip shown in FIG. 1, the main difference of this LED chip is that: the exposed surface of the first conductivity-type semiconductor layer is only disposed in the recess and does not surround the periphery of the light-emitting mesa 11. Therefore, in this case, the second insulating layer 9 does not completely cover the epitaxial stack.

FIG. 17 is a schematic cross-sectional structural diagram of a LED chip provided by one or more embodiments of the present disclosure. The LED chip includes a substrate 1 and a plurality of LED light-emitting units disposed on the surface of the substrate 1 and isolated from each other by trenches. As shown in FIG. 17, the LED light-emitting unit includes:

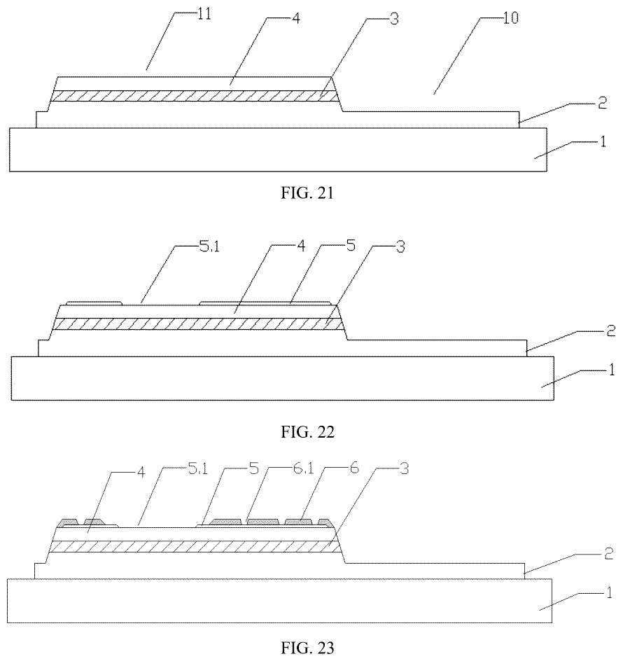

An epitaxial stack disposed on the surface of the substrate 1. The epitaxial stack includes, stacked in sequence along a first direction, a first conductivity-type semiconductor layer 2, an active region 3, and a second conductivity-type semiconductor layer 4. A local region of the epitaxial stack is etched at least to the first conductivity-type semiconductor layer 2 to define a recess 10 and a light-emitting mesa 11 (the schematic can refer to FIG. 21). The first direction is perpendicular to the surface of the substrate 1 and extends from the substrate 1 toward the epitaxial stack.

A transparent conductive layer 5, disposed on the light-emitting mesa 11 and having a first opening 5.1 exposing a portion of the second conductivity-type semiconductor layer 4.

A first insulating layer 6, disposed on a surface of the transparent conductive layer 5 opposite to the epitaxial stack. The first insulating layer 6 has a via region including a plurality of vias 6.1.

A second electrode 8, disposed on a bottom surface of the recess 10 and spaced apart from the light-emitting mesa 11.

A first electrode 7, extending through the first opening 5.1 to contact a top surface of the first insulating layer 6.

A second insulating layer 9, disposed on a surface of the epitaxial stack and exposing at least portions of the second electrode 8 and the first electrode 7. Further, the second insulating layer 9 covers the light-emitting mesa and the recess and exposes portions of the surfaces of the second electrode 8 and the first electrode 7.

The type of substrate 1 is not limited in the LED chip of this embodiment. For example, the substrate 1 may be, but is not limited to, a sapphire substrate 1, a silicon substrate 1, etc. Additionally, the types of the first conductivity-type semiconductor layer 2, the active region 3, and the second conductivity-type semiconductor layer 4 of the epitaxial stack are also not limited in the LED chip of this embodiment. In embodiments of the present disclosure, the first conductivity-type semiconductor layer 2 may be an N-type semiconductor layer, and correspondingly, the second conductivity-type semiconductor layer 4 may be a P-type semiconductor layer. For instance, the first conductivity-type semiconductor layer 2 may be, but is not limited to, an N-type gallium nitride layer, and correspondingly, the second conductivity-type semiconductor layer 4 may be, but is not limited to, a P-type gallium nitride layer.

In order to highlight the technical features of the present disclosure, the embodiment drawing only schematically shows one epitaxial stack unit. In practical product applications, it may include thousands or tens of thousands of epitaxial stack units, depending on the application of the LED chip product, which is not limited herein.

In one or more embodiments of the present disclosure, the first insulating layer 6 includes a first region and a second region. The first region is located below the first electrode 7, and the second region includes all regions of the first insulating layer 6 other than the first region. The via region is located in the second region.

In one or more embodiments of the present disclosure, the via region is located above the light-emitting mesa 11.

In one or more embodiments of the present disclosure, each of the vias 6.1 exposes a portion of the surface of the transparent conductive layer 5.

In one or more embodiments of the present disclosure, a surface area of the light-emitting mesa 11 is S₃, and a total surface area of all the vias 6.1 is S₄, such that 0.1*S₃≤S₄≤0.9*S₃.

In one or more embodiments of the present disclosure, the first insulating layer 6 exposes a portion of the transparent conductive layer 5 to form a step, and the first electrode 7 extends to the surface of the first insulating layer 6 via the step.

In one or more embodiments of the present disclosure, a projection of the first electrode 7 on the transparent conductive layer 5 and a projection of the first electrode 7 on the first insulating layer 6 have an overlapping region with an area Sₐ, and a projection area of the first electrode 7 on the transparent conductive layer 5 is S₁, such that 0<Sₐ≤S_{1/2}.

In one or more embodiments of the present disclosure, the step is disposed around an edge of the first opening 5.1.

In one or more embodiments of the present disclosure, the second insulating layer 9 covers the light-emitting mesa and the recess while exposing a surface of the first conductivity-type semiconductor layer 2.

In one or more embodiments of the present disclosure, the transparent conductive layer 5 covers at least 80% of the area of the light-emitting mesa 11 excluding the first opening 5.1. Further, an edge of the transparent conductive layer 5 is located inward from an edge of the second conductivity-type semiconductor layer 4, with a distance d between them. This distance d is not greater than 2.5 μm. In one or more embodiments of the present disclosure, the distance d is not greater than 1.5 μm, for example, 1 μm. By reducing the distance from the edge of the transparent conductive layer 5 to the edge of the second conductivity-type semiconductor layer 4, the area of the transparent conductive layer 5 is increased, thereby increasing the area of the light-emitting region and achieving further enhancement of the LED's brightness.

In one or more embodiments of the present disclosure, the first electrode 7 has a metal reflective layer.

In one or more embodiments of the present disclosure, a bottom layer of the first electrode 7 is the metal reflective layer.

In one or more embodiments of the present disclosure, the metal reflective layer includes one or more of Ag, Ni, Al, Rh, Pd, Ir, Ru, Mg, Zn, Pt, and Au.

In one or more embodiments of the present disclosure, the transparent conductive layer 5 includes a metal thin film or a metal oxide layer.

In one or more embodiments of the present disclosure, the metal thin film includes one or more of gold, silver, platinum, copper, aluminum, chromium, and palladium.

In one or more embodiments of the present disclosure, the metal oxide layer includes one or more of indium oxide, indium tin oxide, zirconium oxide, cadmium oxide, and titanium nitride.

According to the LED chip provided by embodiments of the present disclosure, through the arrangement including: the epitaxial stack including the first conductivity-type semiconductor layer 2, the active region 3, and the second conductivity-type semiconductor layer 4 stacked in sequence along the first direction; the local region of the epitaxial stack being etched at least to the first conductivity-type semiconductor layer 2 to form the recess 10 and the light-emitting mesa 11; the transparent conductive layer 5 disposed on the light-emitting mesa 11 and having the first opening 5.1 exposing a portion of the second conductivity-type semiconductor layer 4; the first insulating layer 6 being formed on the surface of the transparent conductive layer 5 opposite to the epitaxial stack, and the first insulating layer 6 having a via region including a plurality of vias 6.1; the second electrode 8 disposed on a bottom surface of the recess 10 and spaced apart from the light-emitting mesa 11; the first electrode 7 through the first opening 5.1 to contact a top surface of the first insulating layer 6; and the second insulating layer 9 disposed on the surface of the epitaxial stack and exposing at least portions of the second electrode 8 and the first electrode 7. Based on the above arrangement, the first insulating layer 6 is disposed on the surface of the transparent conductive layer 5, and the first insulating layer 6 has a via region including a plurality of vias 6.1. The pattern formed by the vias 6.1 alters the surface structure of the LED, helping to reduce total internal reflection and allowing more light to escape through the vias 6.1. Furthermore, in this technical solution, a composite region is formed among the first insulating layer 6, the transparent conductive layer 5, the second insulating layer 9, and the first electrode 7. Thus, an ODR structure is formed through the inter-structural relationships among the transparent conductive layer 5, the first insulating layer 6, the first electrode 7, and the second insulating layer 9. Light can undergo total internal reflection in this composite region, so that light corresponding to the composite region under the first electrode 7 is reflected and extracted from the upper surface of the LED chip, thereby effectively enhancing light extraction efficiency. Simultaneously, based on the above arrangement, the second insulating layer 9 is disposed on the surface of the epitaxial stack and on portions of the surfaces of the second electrode 8/first electrode 7. At the edge of the first electrode 7, the first insulating layer 6 and the second insulating layer 9, extending in different directions, can form a connecting structure with an angle. This can effectively alleviate the diffusion of tensile stress generated in the LED chip under special environments (such as high temperature and high pressure), thereby reducing the risk of functional dielectric layers (such as the transparent conductive layer 5, insulating layers, etc.) being cracked or fractured during bonding, which would affect the reliability of the LED chip. Moreover, the dual protection provided by the first insulating layer 6 and the second insulating layer 9 enhances the moisture resistance capability of the LED chip.

In one or more embodiments of the present disclosure, by arranging that: the first insulating layer 6 includes a first region and a second region, the first region is located below the first electrode 7, and the second region includes all regions of the first insulating layer 6 other than the first region; then the via region is located in the second region. Thus, while ensuring the total reflection effect below the first electrode 7 (i.e., the first region) and avoiding light absorption by the electrode, the pattern structure of the vias 6.1 improves the light extraction rate from the light-emitting surface (i.e., the second region).

In one or more embodiments of the present disclosure, by arranging the first insulating layer 6 to expose a portion of the transparent conductive layer 5 to form a step, and the first electrode 7 extending to the surface of the first insulating layer 6 via the step, the electrode contact area can be increased through the step, thereby dispersing stress and reducing the risk of local failure.

In one or more embodiments of the present disclosure, by arranging that: the projection of the first electrode 7 on the transparent conductive layer 5 and the projection of the first electrode 7 on the first insulating layer 6 have an overlapping region with an area Sa, and the projection area of the first electrode 7 on the transparent conductive layer 5 is S₁, such that 0<Sₐ≤S_{1/2}. Thus, while ensuring the contact area between the first electrode 7 and the transparent conductive layer 5 to reduce contact resistance, the size of the composite region area is ensured to improve the ODR reflection effect.

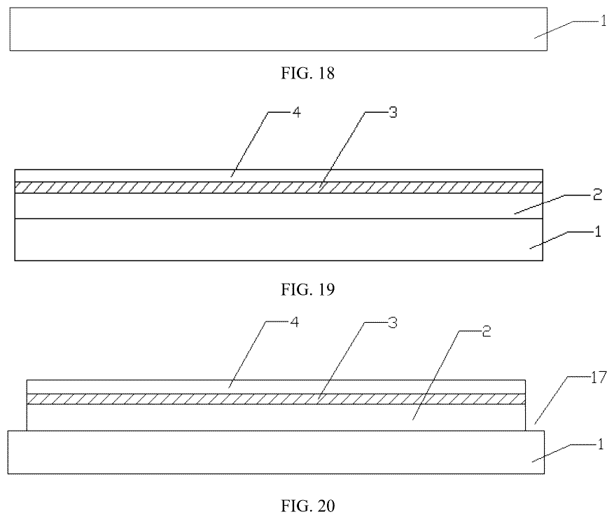

One or more embodiments of the present disclosure provide a method for manufacturing a LED chip, used for manufacturing the LED chip shown in FIG. 17. The manufacturing method includes the following steps:
S01B: As shown in FIG. 18, provide a substrate 1.

The type of substrate 1 is not limited in the LED chip of this embodiment. For example, the substrate 1 may be, but is not limited to, a sapphire substrate 1, a silicon substrate 1.
S02B: As shown in FIG. 19, grow an epitaxial stack. The epitaxial stack includes, stacked in sequence along a first direction, a first conductivity-type semiconductor layer 2, an active region 3, and a second conductivity-type semiconductor layer 4. The first direction is perpendicular to the surface of the substrate 1 and extends from the substrate 1 toward the epitaxial stack.

In one or more embodiments of the present disclosure, the first conductivity-type semiconductor layer 2 may be an N-type semiconductor layer, and correspondingly, the second conductivity-type semiconductor layer 4 may be a P-type semiconductor layer. For instance, the first conductivity-type semiconductor layer 2 may be, but is not limited to, an N-type gallium nitride layer, and correspondingly, the second conductivity-type semiconductor layer 4 may be, but is not limited to, a P-type gallium nitride layer.
S03B: As shown in FIG. 20, perform deep etching on the epitaxial stack to expose the surface of the substrate 1, forming a plurality of mutually independent epitaxial stack units separated by trenches.

In one or more embodiments of the present disclosure, performing deep etching on the epitaxial stack to expose the surface of substrate 1 and forming a plurality of epitaxial stack units arranged spaced apart by trenches includes: using an Inductively Coupled Plasma (ICP) process with etching gases including Cl₂, Ar, and O₂. However, this is not limiting in the present disclosure and depends on the specific situation.

In order to highlight the technical features of the present disclosure, the drawing only schematically shows one epitaxial stack unit. In practical product applications, it may include thousands or tens of thousands of epitaxial stack units, depending on the application of the LED chip product, which is not limited herein.
S04B: As shown in FIG. 21, etch each of the epitaxial stack units to partially expose the first conductivity-type semiconductor layer 2, thereby forming a recess 10 and a light-emitting mesa 11.

In one or more embodiments of the present disclosure, etching the epitaxial stack to form the recess 10 and the light-emitting mesa 11 includes: using an Inductively Coupled Plasma (ICP) process with etching gases including Cl₂, Ar, and O₂. However, this is not limiting in the present disclosure and depends on the specific situation.

In one or more embodiments of the present disclosure, the recess 10 is disposed at a first end of the LED light-emitting unit.

In one or more embodiments of the present disclosure, the exposed surface of the first conductivity-type semiconductor layer is disposed surrounding the periphery of the light-emitting mesa 11.
S05B: As shown in FIG. 22, manufacture a transparent conductive layer 5 on the light-emitting mesa 11, wherein the transparent conductive layer 5 has a first opening 5.1 exposing a portion of the second conductivity-type semiconductor layer 4.

In one or more embodiments of the present disclosure, the transparent conductive layer 5 covers at least 80% of the area of the light-emitting mesa 11 excluding the first opening 5.1. Further, an edge of the transparent conductive layer 5 is located inward from an edge of the second conductivity-type semiconductor layer 4, with a distance d between them. This distance d is not greater than 2.5 μm. In one or more embodiments of the present disclosure, the distance d is not greater than 1.5 μm, for example, 1 μm. By reducing the distance from the edge of the transparent conductive layer 5 to the edge of the second conductivity-type semiconductor layer 4, the area of the transparent conductive layer 5 is increased, thereby increasing the area of the light-emitting region and achieving further enhancement of the LED's brightness.

In one or more embodiments of the present disclosure, the transparent conductive layer 5 includes a metal thin film or a metal oxide layer.

In one or more embodiments of the present disclosure, the metal thin film includes one or more of gold, silver, platinum, copper, aluminum, chromium, and palladium.

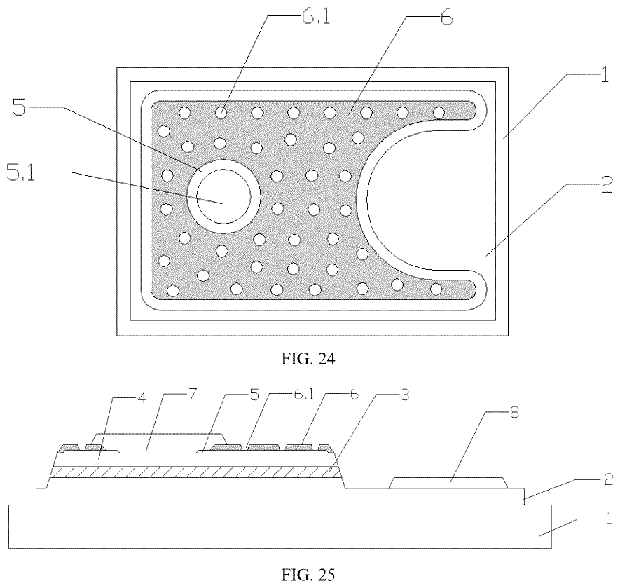

In one or more embodiments of the present disclosure, the metal oxide layer includes one or more of indium oxide, indium tin oxide, zirconium oxide, cadmium oxide, and titanium nitride.
S06B: Deposit a transparent dielectric layer covering exposed surfaces of each epitaxial stack unit. Subsequently, apply a photoresist on the surface of the transparent dielectric layer and use a mask and etching process to obtain the transparent dielectric layer located on the surface of the transparent conductive layer 5, thereby forming the first insulating layer 6 as shown in FIGS. 23 and 24. The first insulating layer 6 has a via region including a plurality of vias 6.1.

In one or more embodiments of the present disclosure, the transparent dielectric layer includes one or more of materials such as silicon oxide, titanium oxide, silicon nitride, aluminum oxide, magnesium fluoride, spin-on glass (SOG), polymer, etc.

In one or more embodiments of the present disclosure, the first insulating layer 6 exposes a portion of the transparent conductive layer 5 to form a step, and the first electrode 7 extends to the surface of the first insulating layer 6 via the step.

In one or more embodiments of the present disclosure, the step is disposed around an edge of the first opening 5.1.
S07B: As shown in FIG. 25, manufacture the second electrode 8 and the first electrode 7.

The second electrode 8 is disposed on a bottom surface of the recess 10 and spaced apart from the light-emitting mesa 11.

The first electrode 7 extends through the first opening 5.1 to contact a top surface of the first insulating layer 6. Further, the first electrode 7 extends to the surface of the first insulating layer 6 via the step.

In one or more embodiments of the present disclosure, a projection of the first electrode 7 on the transparent conductive layer 5 and a projection of the first electrode 7 on the first insulating layer 6 have an overlapping region with an area Sₐ, and a projection area of the first electrode 7 on the transparent conductive layer 5 is S₁, such that 0<Sₐ≤S_{1/2}.

In this embodiment, the second electrode 8 and the first electrode 7 may be metal electrodes, i.e., made of metal materials, such as at least one of nickel, gold, chromium, titanium, platinum, palladium, rhodium, iridium, aluminum, tin, indium, tantalum, copper, cobalt, iron, ruthenium, zirconium, tungsten, and molybdenum, or at least one of alloys or stacks of the above materials.

In one or more embodiments of the present disclosure, the first electrode 7 has a metal reflective layer.

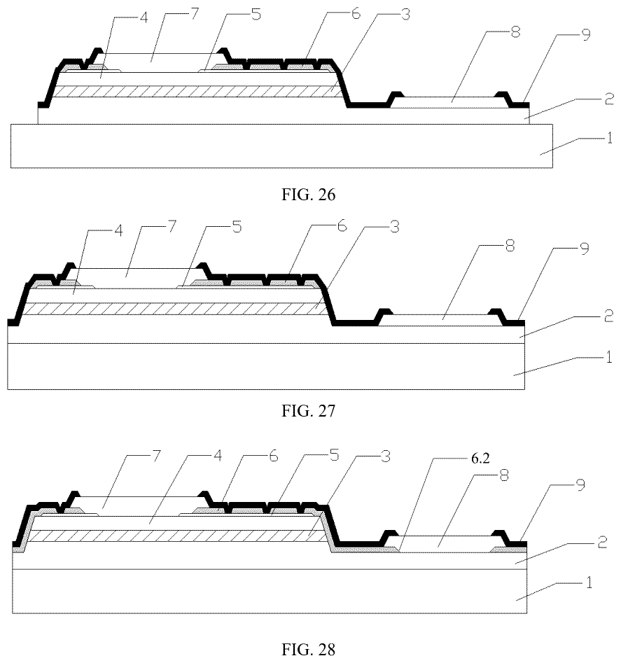

In one or more embodiments of the present disclosure, a bottom layer of the first electrode 7 is the metal reflective layer. Further, the metal reflective layer includes one or more of Ag, Ni, Al, Rh, Pd, Ir, Ru, Mg, Zn, Pt, and Au.
S08B: As shown in FIG. 26, manufacture a second insulating layer 9. It is disposed on a surface of the epitaxial stack and exposes at least portions of the second electrode 8 and the first electrode 7. Further, the second insulating layer 9 covers the light-emitting mesa and the recess and exposes portions of the surfaces of the second electrode 8 and the first electrode 7.

In one or more embodiments of the present disclosure, the second insulating layer 9 includes, but is not limited to, one or more of silicon oxide and magnesium fluoride.

In one or more embodiments of the present disclosure, the second insulating layer 9 covers the light-emitting mesa and the recess while exposing a surface of the first conductivity-type semiconductor layer 2.
S09B: Perform dicing along the trenches to finally obtain a plurality of LED light-emitting units as shown in FIG. 27.

In one or more embodiments of the present disclosure, the first insulating layer 6 includes a first region and a second region. The first region is located below the first electrode 7, and the second region includes all regions of the first insulating layer 6 other than the first region. The via region is located in the second region.

In one or more embodiments of the present disclosure, the via region is located above the light-emitting mesa 11.

In one or more embodiments of the present disclosure, each of the vias 6.1 exposes a portion of the surface of the transparent conductive layer 5.

FIG. 28 is a schematic cross-sectional structural diagram of a LED chip provided by one or more embodiments of the present disclosure. Compared to the LED chip shown in FIG. 17, the main difference of this LED chip is that: the first insulating layer 6 extends from the surface of the transparent conductive layer 5 to the recess 10 and has a third opening 6.2 exposing a portion of the first conductivity-type semiconductor layer 2. The second electrode 8 is formed on the surface of the recess 10 by being embedded in the third opening 6.2. Thereby, the stability of the second electrode 8 is further improved.

In one or more embodiments of the present disclosure, the first insulating layer 6 is disposed on the substrate 1 by being held in the trenches and surrounds the periphery of the epitaxial stack.

FIG. 29A is a schematic cross-sectional structural diagram of a LED chip provided by one or more embodiments of the present disclosure. Compared to the LED chip shown in FIG. 17, the main difference of this LED chip is that: a current blocking layer 13 is disposed on the bottom surface of the first opening 5.1. The current blocking layer 13 and the transparent conductive layer 5 form a spacing groove, and the first electrode 7 is embedded in the spacing groove to contact the second conductivity-type semiconductor layer 4. This improves current crowding, promotes lateral current spreading, and simultaneously, the inter-structural relationships among the first electrode 7 (metal reflector), the first insulating layer 6 (dielectric layer), the spacing groove, the current blocking layer 13 (dielectric layer), and the transparent conductive layer 5 (conductive layer) form another ODR structure, which is beneficial for increasing the area of the total reflection layer under the electrode, further enhancing reflection efficiency.

In one or more embodiments of the present disclosure, the projection area of the current blocking layer 13 on the transparent conductive layer 5 is S₂, and the bottom surface area of the first opening 5.1 is S₃, such that 0<S₂≤S_{3/2}. Thus, while ensuring current blocking and total reflection effects, the contact area between the first electrode 7 and the second conductivity-type semiconductor layer 4 is ensured to improve the reliability of electrode wire bonding. The specific area of the current blocking layer 13 needs to meet the above requirements. The shape of the current blocking layer 13 may be trapezoidal, square, or rectangular.

In one or more embodiments of the present disclosure, the first insulating layer 6 and the current blocking layer 13 may be formed simultaneously by using photolithography to etch the transparent dielectric layer in step S06B.

FIG. 29B is a schematic cross-sectional structural diagram of a LED chip provided by one or more embodiments of the present disclosure. Compared to the LED chip shown in FIG. 17, the main difference of this LED chip is that it includes a current blocking layer 13. The current blocking layer 13 extends through the first opening 5.1 to the surface of the transparent conductive layer 5. The current blocking layer 13 and the first insulating layer 6 are spaced apart by a spacing groove, and the spacing groove between the current blocking layer 13 and the first insulating layer 6 exposes a portion of the transparent conductive layer 5 surrounding the periphery of the current blocking layer 13. The first electrode 7 covers the current blocking layer 13 by being embedded in the spacing groove between the current blocking layer 13 and the first insulating layer 6, and extends to the surface of the first insulating layer 6, so that it has a composite region with the transparent conductive layer 5 and the first insulating layer 6 along the first direction. With this arrangement, an ODR structure is formed through the inter-structural relationships among the first electrode 7 (metal reflector), the first insulating layer 6 (dielectric layer), the spacing groove, the current blocking layer 13 (dielectric layer), and the transparent conductive layer 5 (conductive layer). Light can undergo total internal reflection in the composite region of the first electrode 7 with the transparent conductive layer 5 and the first insulating layer 6, so that light corresponding to this composite region under the first electrode 7 is reflected and extracted from the upper surface of the LED chip, thereby effectively enhancing light extraction efficiency. Simultaneously, the current blocking layer 13 disposed directly below the first electrode 7 can effectively prevent current crowding caused by the current injected from the first electrode 7 (P-type electrode) of the LED chip concentrating directly under the electrode.

In one or more embodiments of the present disclosure, the area of the composite region of the first electrode 7 with the transparent conductive layer 5 and the first insulating layer 6 is S₁₀ and the area of the bottom surface of the first opening 5.1 is S₃, such that 0.5*S₁₀≤S₃≤3*S₁₀. Thus, while ensuring the contact area between the first electrode 7 and the transparent conductive layer 5 to reduce contact resistance, the area size of the composite region of the first electrode 7 with the transparent conductive layer 5 and the first insulating layer 6 is ensured to improve the ODR reflection effect.

In one or more embodiments of the present disclosure, the first insulating layer 6 and the current blocking layer 13 may be formed simultaneously by using photolithography to etch the transparent dielectric layer in step S06B.

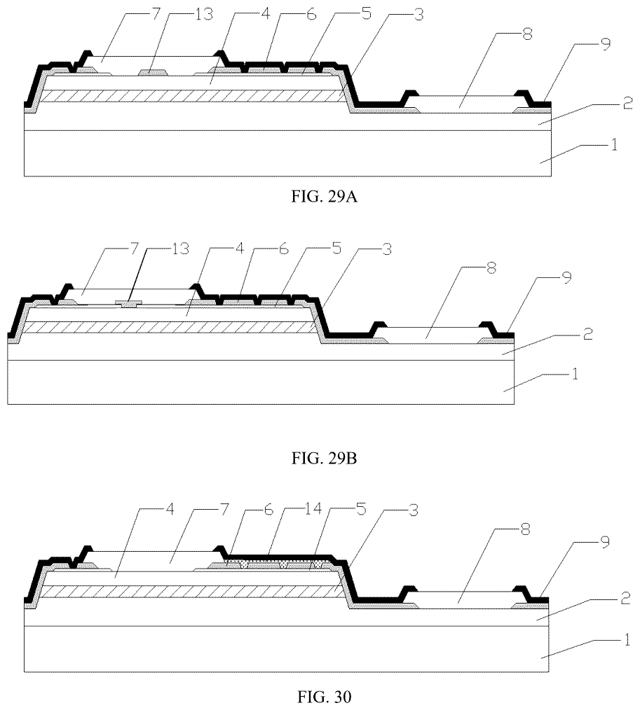

FIG. 30 is a schematic cross-sectional structural diagram of a LED chip provided by one or more embodiments of the present disclosure. Compared to the LED chip shown in FIG. 17, the main difference of this chip is that: the second electrode 8 includes a second electrode pad disposed at a first end of the LED light-emitting unit. The first opening 5.1 is formed at a second end of the LED light-emitting unit. The first electrode 7 includes a first electrode pad and at least one electrode extension strip 14 connected to the first electrode pad. The first electrode pad extends through the first opening 5.1 to contact a top surface of the first insulating layer 6, and the electrode extension strip 14 extends from the first electrode pad towards the second end of the LED light-emitting unit. Further, the electrode extension strip 14 has a forked structure, and the forked structure makes contact with the transparent conductive layer 5 by penetrating through portions of the vias 6.1 and embedding into the first insulating layer 6. This allows the current to enter the vias 6.1 through the forked fingers for guided spreading, ensuring that the current can reach the desired locations through the first insulating layer 6. Consequently, the current can be distributed more uniformly, reducing current crowding, allowing more regions to emit light effectively, and further improving overall brightness.

In one or more embodiments of the present disclosure, the second electrode 8 may also include an electrode extension strip 14 connected to the second electrode pad and extending towards the first end, which is not elaborated herein.

The material, shape, and structure of the electrode extension strip 14 need to meet the requirements for electrode extension and guidance.

In other embodiments, a combination of the embodiments shown in FIG. 30 and FIG. 29A may be used, which is not elaborated herein.

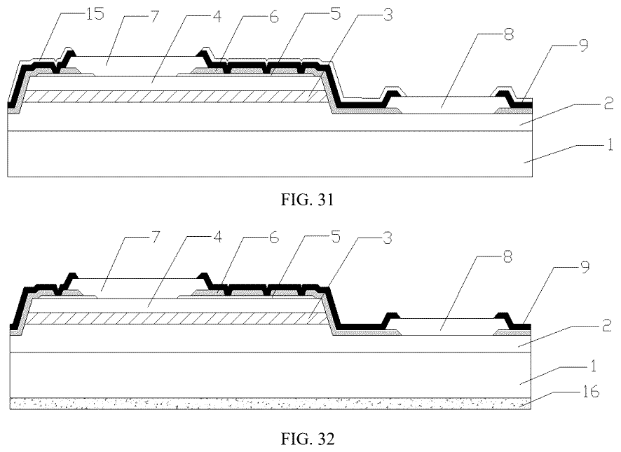

FIG. 31 is a schematic cross-sectional structural diagram of a LED chip provided by one or more embodiments of the present disclosure. Compared to the LED chip shown in FIG. 17, the main difference of this LED chip is that: the LED chip further includes a refractive-index matching layer 15 disposed on a surface of the second insulating layer 9 opposite to the epitaxial stack and forming a graded-index structure with the second insulating layer 9, further enhancing light extraction efficiency. In one or more embodiments of the present disclosure, a refractive index of the refractive-index matching layer 15 is not less than a refractive index of the second insulating layer 9. Furthermore, if the first insulating layer 6 or the second insulating layer 9 includes a layered structure composed of one or more of SiO₂ and MgF₂, then the refractive-index matching layer 15 may include a layered structure composed of one or more of TiO₂, Si₃N₄, and Al₂O₃. In one or more embodiments of the present disclosure, the second insulating layer 9 is a SiO₂ layer, and the refractive-index matching layer 15 is an Al₂O₃ layer. Benefiting from the excellent passivation properties of Al₂O₃, it can effectively cover dangling bonds and defect states on the SiO₂ surface, reducing non-radiative recombination of carriers at the surface. The reduction in non-radiative recombination directly improves the internal quantum efficiency (IQE), meaning more electrical energy is converted into light energy rather than heat.

FIG. 32 is a schematic cross-sectional structural diagram of a LED chip provided by one or more embodiments of the present disclosure. Compared to the LED chip shown in FIG. 17, the main difference of this LED chip is that: a reflective layer 16 is further disposed on a surface of the substrate 1 opposite to the epitaxial stack. Further, the reflective layer 16 includes a distributed Bragg reflector (DBR) composed of alternating stacks of high-refractive-index material layers and low-refractive-index material layers. Alternatively, the reflective layer may also be a metal reflective layer. Its material needs to meet the requirements for a DBR/metal reflector.

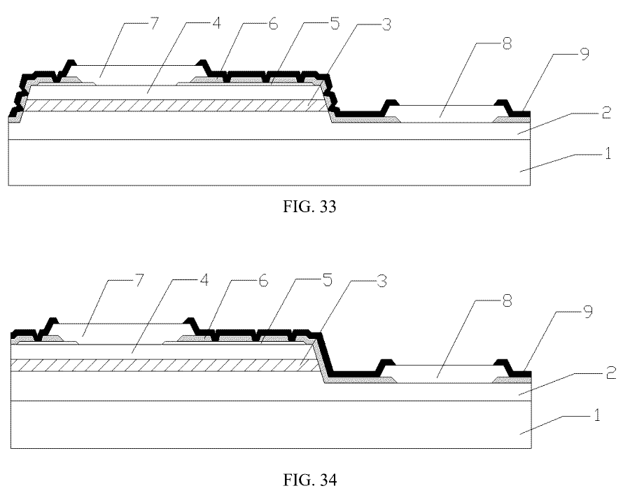

FIG. 33 is a schematic cross-sectional structural diagram of a LED chip provided by one or more embodiments of the present disclosure. Compared to the LED chip shown in FIG. 17, the main difference of this LED chip is that: the via region extends from above the light-emitting mesa 11 to a sidewall of the light-emitting mesa 11. Thereby, it helps reduce total internal reflection at the sidewall of the light-emitting mesa 11, allowing more light to escape through the sidewall.

FIG. 34 is a schematic cross-sectional structural diagram of a LED chip provided by one or more embodiments of the present disclosure. Compared to the LED chip shown in FIG. 17, the main difference of this LED chip is that: the exposed surface of the first conductivity-type semiconductor layer is only disposed in the recess and does not surround the periphery of the light-emitting mesa 11. Therefore, in this case, the second insulating layer 9 does not completely cover the epitaxial stack.

According to one or more embodiments of the present disclosure, a LED chip is provided. The LED chip includes a plurality of LED light-emitting units isolated from one another by a plurality of trenches. The LED light-emitting unit includes: a substrate and an epitaxial stack disposed on a surface of the substrate. The epitaxial stack includes, stacked in sequence along a first direction, a first conductivity-type semiconductor layer, an active region, and a second conductivity-type semiconductor layer. A local region of the epitaxial stack is etched at least to the first conductivity-type semiconductor layer to define a recess and a light-emitting mesa. The first direction is perpendicular to the surface of the substrate and extends from the substrate toward the epitaxial stack.

The LED light-emitting unit includes a transparent conductive layer, a first insulating layer, a second insulating layer, a first electrode, and a second electrode. The transparent conductive layer is disposed on the light-emitting mesa and defines a first opening that exposes a portion of the second conductivity-type semiconductor layer.

The first insulating layer is disposed on a surface of the transparent conductive layer opposite to the epitaxial stack.

The second electrode is disposed on a bottom surface of the recess and spaced apart from the light-emitting mesa.

The first electrode extends to a portion of a surface of the first insulating layer through the first opening.

The second insulating layer is disposed on a surface of the epitaxial stack and exposes at least portions of the second electrode and the first electrode. Further, the second insulating layer covers the light-emitting mesa and the recess and exposes portions of the surfaces of the second electrode and the first electrode.

The type of substrate is not limited in the LED chip of this embodiment. For example, the substrate may be, but is not limited to, a sapphire substrate, a silicon substrate, etc. Additionally, the types of the first conductivity-type semiconductor layer, the active region, and the second conductivity-type semiconductor layer of the epitaxial stack are also not limited in the LED chip of this embodiment. In embodiments of the present disclosure, the first conductivity-type semiconductor layer may be an N-type semiconductor layer, and correspondingly, the second conductivity-type semiconductor layer may be a P-type semiconductor layer. For instance, the first conductivity-type semiconductor layer may be, but is not limited to, an N-type gallium nitride layer, and correspondingly, the second conductivity-type semiconductor layer may be, but is not limited to, a P-type gallium nitride layer.

In order to highlight the technical features of the present disclosure, the drawings only schematically show one epitaxial stack unit. In practical product applications, it may include thousands or tens of thousands of epitaxial stack units, depending on the application of the LED chip product, which is not limited herein.

In one or more embodiments of the present disclosure, the first insulating layer exposes a portion of the transparent conductive layer to form a step, and the first electrode extends to the surface of the first insulating layer through the step.

In one or more embodiments of the present disclosure, a projection of the first electrode on the transparent conductive layer and a projection of the first electrode on the first insulating layer have an overlapping region with an area Sₐ, and a projection area of the first electrode on the transparent conductive layer is S₁, such that 0<Sₐ≤S_{1/2}.

In one or more embodiments of the present disclosure, the step is disposed around an edge of the first opening.

In one or more embodiments of the present disclosure, a current blocking layer is disposed on a bottom surface of the first opening.

In one or more embodiments of the present disclosure, the current blocking layer and the transparent conductive layer form a spacing groove, and the first electrode is embedded in the spacing groove to contact the second conductivity-type semiconductor layer.

In one or more embodiments of the present disclosure, a projection area of the current blocking layer on the transparent conductive layer is S₂, and an bottom surface area of the first opening is S₃, such that 0<S₂≤S_{3/2}.

In one or more embodiments of the present disclosure, the first insulating layer and the current blocking layer are formed simultaneously by using photolithography to etch a transparent dielectric layer.

In one or more embodiments of the present disclosure, the transparent dielectric layer includes one or more of silicon oxide, silicon nitride, aluminum oxide, and magnesium fluoride.

In one or more embodiments of the present disclosure, a third insulating layer is further disposed on the surface of the recess, and the third insulating layer has a second opening exposing a portion of the first conductivity-type semiconductor layer. The second electrode is disposed on a surface of the third insulating layer by being embedded in the second opening.

In one or more embodiments of the present disclosure, the first insulating layer and the third insulating layer are formed simultaneously by using photolithography to etch a transparent dielectric layer.

In one or more embodiments of the present disclosure, the LED chip further includes a refractive-index matching layer disposed on a surface of the second insulating layer opposite to the epitaxial stack and forming a graded-index structure with the second insulating layer, thereby further enhancing light extraction efficiency. In one or more embodiments of the present disclosure, a refractive index of the refractive-index matching layer is not less than a refractive index of the second insulating layer.

Furthermore, if the first insulating layer or the second insulating layer includes a layered structure composed of one or more of SiO₂ and MgF₂, then the refractive-index matching layer may include a layered structure composed of one or more of TiO₂, Si₃N₄, and Al₂O₃. In one or more embodiments of the present disclosure, the second insulating layer is a SiO₂ layer, and the refractive-index matching layer is an Al₂O₃ layer. Benefiting from the excellent passivation properties of Al₂O₃, it can effectively cover dangling bonds and defect states on the SiO₂ surface, reducing non-radiative recombination of carriers at the surface. The reduction in non-radiative recombination directly improves the internal quantum efficiency (IQE), meaning more electrical energy is converted into light energy rather than heat.

In one or more embodiments of the present disclosure, a reflective layer is further disposed on a surface of the substrate opposite to the epitaxial stack. Further, the reflective layer includes a distributed Bragg reflector (DBR) composed of alternating stacks of high-refractive-index material layers and low-refractive-index material layers. Alternatively, the reflective layer may also be a metal reflective layer.

In one or more embodiments of the present disclosure, the second electrode includes a second electrode pad disposed at a first end of the LED light-emitting unit. The first opening is formed at a second end of the LED light-emitting unit. The first electrode includes a first electrode pad and at least one electrode extension strip connected to the first electrode pad. The first electrode pad extends through the first opening to contact the top surface of the first insulating layer, and the electrode extension strip extends from the first electrode pad towards the second end of the LED light-emitting unit.

In one or more embodiments of the present disclosure, the second electrode may also include an electrode extension strip connected to the second electrode pad and extending towards the first end.

In one or more embodiments of the present disclosure, at least a portion of the electrode extension strip makes contact with the transparent conductive layer.

In one or more embodiments of the present disclosure, the electrode extension strip has a forked structure, and the forked structure makes contact with the transparent conductive layer by penetrating through the first insulating layer. Alternatively, the transparent conductive layer has through-holes, and the electrode extension strip has forked fingers, and the forked fingers are formed and held in the through-holes of the transparent conductive layer.

In one or more embodiments of the present disclosure, the second insulating layer covers the light-emitting mesa and the recess while exposing a surface of the first conductivity-type semiconductor layer.

In one or more embodiments of the present disclosure, the transparent conductive layer covers at least 80% of the area of the light-emitting mesa excluding the first opening.

In one or more embodiments of the present disclosure, the first electrode has a metal reflective layer.

In one or more embodiments of the present disclosure, a bottom layer of the first electrode is the metal reflective layer.

In one or more embodiments of the present disclosure, the metal reflective layer includes one or more of Ag, Ni, Al, Rh, Pd, Ir, Ru, Mg, Zn, Pt, and Au.

In one or more embodiments of the present disclosure, the transparent conductive layer includes a metal thin film or a metal oxide layer.

In one or more embodiments of the present disclosure, the metal thin film includes one or more of gold, silver, platinum, copper, aluminum, chromium, and palladium.

In one or more embodiments of the present disclosure, the metal oxide layer includes one or more of indium oxide, indium tin oxide, zirconium oxide, cadmium oxide, and titanium nitride.

In one or more embodiments of the present disclosure, the first insulating layer has a via region including a plurality of vias.

In one or more embodiments of the present disclosure, the first insulating layer includes a first region and a second region. The first region is located below the first electrode, and the second region includes all areas of the first insulating layer other than the first region. The via region is located in the second region.

In one or more embodiments of the present disclosure, the second electrode extends to the surface of the first insulating layer.

In one or more embodiments of the present disclosure, the via region is located above the light-emitting mesa.

In one or more embodiments of the present disclosure, each of the vias exposes a portion of the surface of the transparent conductive layer.

In one or more embodiments of the present disclosure, at least one via of the plurality of vias extends downward from the first insulating layer to a surface of the second conductivity-type semiconductor layer.

In one or more embodiments of the present disclosure, the via region extends from above the light-emitting mesa to a sidewall of the light-emitting mesa.

In one or more embodiments of the present disclosure, the first insulating layer extends from the surface of the transparent conductive layer to the recess and has a third opening exposing a portion of the first conductivity-type semiconductor layer. The second electrode is formed on the surface of the recess by being embedded in the third opening.

In one or more embodiments of the present disclosure, a surface area of the light-emitting mesa is S₃, and a total surface area of all the vias is S₄, such that 0.1*S₃≤S₄≤0.9*S₃.

According to a LED chip provided by an embodiment of the present disclosure, through the arrangement including: the epitaxial stack including the first conductivity-type semiconductor layer, the active region, and the second conductivity-type semiconductor layer stacked in sequence along the first direction; the local region of the epitaxial stack being etched at least to the first conductivity-type semiconductor layer to form the recess and the light-emitting mesa; the transparent conductive layer disposed on the light-emitting mesa and having the first opening exposing a portion of the second conductivity-type semiconductor layer; the first insulating layer being formed on the surface of the transparent conductive layer opposite to the epitaxial stack; the second electrode disposed on a bottom surface of the recess and spaced apart from the light-emitting mesa; the first electrode extending through the first opening to contact a top surface of the first insulating layer; and the second insulating layer disposed on the surface of the epitaxial stack and exposing at least portions of the second electrode and the first electrode. Based on the above arrangement, a composite region is formed among the first insulating layer, the transparent conductive layer, the second insulating layer, and the first electrode. Thereby, an ODR (Omni-Directional Reflector) structure is formed through the inter-structural relationships among the transparent conductive layer, the first insulating layer, the first electrode, and the second insulating layer. Light can undergo total internal reflection in this composite region, so that light corresponding to the composite region under the first electrode is reflected and extracted from the upper surface of the LED chip, thereby effectively enhancing light extraction efficiency.

According to a LED chip provided by an embodiment of the present disclosure, through the arrangement including: the epitaxial stack including the first conductivity-type semiconductor layer, the active region, and the second conductivity-type semiconductor layer stacked in sequence along the first direction; the local region of the epitaxial stack being etched at least to the first conductivity-type semiconductor layer to form the recess and the light-emitting mesa; the transparent conductive layer disposed on the light-emitting mesa and having the first opening exposing a portion of the second conductivity-type semiconductor layer; the first insulating layer being formed on the surface of the transparent conductive layer opposite to the epitaxial stack, and the first insulating layer having a via region including a plurality of vias; the second electrode disposed on a bottom surface of the recess and spaced apart from the light-emitting mesa; the first electrode extending through the first opening to contact a top surface of the first insulating layer; and the second insulating layer disposed on the surface of the epitaxial stack and exposing at least portions of the second electrode and the first electrode. Based on the above arrangement, the first insulating layer is disposed on the surface of the transparent conductive layer, and the first insulating layer has a via region including a plurality of vias. The pattern formed by the vias alters the surface structure of the LED, helping to reduce total internal reflection and allowing more light to escape through the vias. Furthermore, in this technical solution, a composite region is formed among the first insulating layer, the transparent conductive layer, the second insulating layer, and the first electrode. Thus, an ODR structure is formed through the inter-structural relationships among the transparent conductive layer, the first insulating layer, the first electrode, and the second insulating layer. Light can undergo total internal reflection in this composite region, so that light corresponding to the composite region under the first electrode is reflected and extracted from the upper surface of the LED chip, thereby effectively enhancing light extraction efficiency.

According to a LED chip provided by an embodiment of the present disclosure, the second insulating layer is disposed on the surface of the epitaxial stack and on portions of the surfaces of the second electrode/first electrode. At the edge of the first electrode, the first insulating layer and the second insulating layer, extending in different directions, can form a connecting structure with an angle. This can effectively alleviate the diffusion of tensile stress generated in the LED chip under special environments (such as high temperature and high pressure), thereby reducing the risk of functional dielectric layers (such as the transparent conductive layer, insulating layers, etc.) being cracked or fractured during bonding, which would affect the reliability of the LED chip. Moreover, the dual protection provided by the first insulating layer and the second insulating layer enhances the moisture resistance capability of the LED chip.

According to a LED chip provided by an embodiment of the present disclosure, the first insulating layer includes a first region and a second region. The first region is located below the first electrode, and the second region includes all areas of the first insulating layer other than the first region. The via region is located in the second region. Thereby, while ensuring the total reflection effect below the first electrode (i.e., the first region) and avoiding light absorption by the electrode, the pattern structure of the vias improves the light extraction rate from the light-emitting surface (i.e., the second region).

According to a LED chip provided by an embodiment of the present disclosure, the first insulating layer exposes a portion of the transparent conductive layer to form a step, and the first electrode extends to the surface of the first insulating layer through the step. This step can increase the electrode contact area, thereby dispersing stress and reducing the risk of local failure.

According to a LED chip provided by an embodiment of the present disclosure, the projection of the first electrode on the transparent conductive layer and the projection of the first electrode on the first insulating layer have an overlapping region with an area Sₐ, and the projection area of the first electrode on the transparent conductive layer is S₁, such that 0<Sₐ≤S_{1/2}. Thus, while ensuring the contact area between the first electrode and the transparent conductive layer to reduce contact resistance, the size of the composite region area is ensured to improve the ODR reflection effect.

According to a LED chip provided by an embodiment of the present disclosure, a current blocking layer is disposed on the bottom surface of the first opening. The current blocking layer and the transparent conductive layer form a spacing groove, and the first electrode is embedded in the spacing groove to contact the second conductivity-type semiconductor layer. This improves current crowding, promotes lateral current spreading, and simultaneously, the inter-structural relationships among the first electrode (metal reflector), the first insulating layer (dielectric layer), the spacing groove, the current blocking layer (dielectric layer), and the transparent conductive layer (conductive layer) form another ODR structure, which is beneficial for increasing the area of the total reflection layer under the electrode, further enhancing reflection efficiency. Furthermore, the projection area of the current blocking layer on the transparent conductive layer is S₂, and the bottom surface area of the first opening is S₃, such that 0<S₂≤S_{3/2}. Thus, while ensuring current blocking and total reflection effects, the contact area between the first electrode and the second conductivity-type semiconductor layer is ensured to improve the reliability of electrode wire bonding.

According to a LED chip provided by an embodiment of the present disclosure, the second electrode includes a second electrode pad disposed at a first end of the LED light-emitting unit. The first opening is formed at a second end of the LED light-emitting unit. The first electrode includes a first electrode pad and at least one electrode extension strip connected to the first electrode pad. The first electrode pad extends through the first opening to contact a top surface of the first insulating layer, and the electrode extension strip extends from the first electrode pad towards the second end of the LED light-emitting unit, which better guides and spreads the current through the electrode extension strip, avoiding current crowding.

According to a LED chip provided by an embodiment of the present disclosure, the electrode extension strip has a forked structure, and the forked structure makes contact with the transparent conductive layer by penetrating through portions of the vias and embedding into the first insulating layer. This allows the current to enter the vias through the forked fingers for guided spreading, ensuring that the current can reach the desired locations through the first insulating layer. Consequently, the current can be distributed more uniformly, reducing current crowding, allowing more regions to emit light effectively, and further improving overall brightness.

Based on the above embodiments, in practical application processes, a combination of any two or more of the above embodiments may also be used, depending on the requirements of the specific product's technical solution, which is not limited herein.

The LED chips provided in the above embodiments are also applicable to high-voltage LED chips. The high-voltage LED chip electrically interconnects adjacent LED light-emitting units as described in any of the above items through a bridging electrode. An insulating layer is also provided in the trenches, and the bridging electrode connects two adjacent LED units by disposed on the insulating layer. Their specific structures, performance, and advantages can be referred to the foregoing content and are not elaborated here.

Furthermore, one or more embodiments of the present disclosure also provide a light-emitting device or a lighting device that includes a light-emitting diode. The light-emitting diode employs the LED chip or high-voltage LED chip as provided in the above embodiments. Its specific performance and advantages can be referred to the foregoing content and are not elaborated here.

The devices provided by the embodiments of the present disclosure have the same implementation principles and technical effects as the aforementioned method embodiments. For brevity, parts not mentioned in the device embodiments can refer to the corresponding content in the aforementioned method embodiments. Those skilled in the art can clearly understand that, for the convenience and conciseness of description, the specific working processes of the systems, devices, and units described above can all refer to the corresponding processes in the above method embodiments and will not be repeated here.

The various embodiments in this specification are described in a progressive manner. Each embodiment focuses on explaining the differences from other embodiments. The same or similar parts between the various embodiments can be referred to each other.

Relational terms such as first and second are used merely to distinguish one entity or operation from another entity or operation, and do not necessarily require or imply that there is any such actual relationship or order between these entities or operations. Moreover, the terms “include”, “include”, or any other variants thereof are intended to cover non-exclusive inclusion, so that a product or device that includes a series of elements includes not only those elements, but also other elements not explicitly listed, or elements inherent to such product or device. Without further limitations, an element defined by the phrase “including one . . . ” does not exclude the existence of additional identical elements in the product or device that includes said element.

The above description of the disclosed embodiments enables those skilled in the art to implement or use the present disclosure. Various modifications to these embodiments will be obvious to those skilled in the art. The general principles defined herein can be implemented in other embodiments without departing from the spirit or scope of the present disclosure. Therefore, the scope of the present disclosure will not be limited to the embodiments shown herein but is to conform to the widest scope consistent with the principles and novel features disclosed herein.

What is claimed is:

1. A LED light-emitting unit, comprising:
a substrate;
an epitaxial stack disposed on a surface of the substrate, the epitaxial stack comprising, in sequence along a first direction, a first conductivity-type semiconductor layer, an active region, and a second conductivity-type semiconductor layer, wherein a local region of the epitaxial stack is etched at least to the first conductivity-type semiconductor layer to define a recess and a light-emitting mesa, and wherein the first direction is perpendicular to the surface of the substrate and extends from the substrate toward the epitaxial stack;
a transparent conductive layer disposed on the light-emitting mesa and having a first opening exposing a portion of the second conductivity-type semiconductor layer;
a first insulating layer disposed on a surface of the transparent conductive layer opposite to the epitaxial stack; and
a first electrode extending through the first opening to contact a top surface of the first insulating layer.

2. The LED light-emitting unit according to claim 1, further comprising:
a second electrode disposed on a bottom surface of the recess and spaced apart from the light-emitting mesa; and
a second insulating layer disposed on a surface of the epitaxial stack and exposing at least portions of the second electrode and the first electrode.

3. The LED light-emitting unit according to claim 1, wherein the first insulating layer exposes a portion of the transparent conductive layer to form a step, and the first electrode extends to the surface of the first insulating layer through the step.

4. The LED light-emitting unit according to claim 1, wherein a projection of the first electrode on the transparent conductive layer and a projection of the first electrode on the first insulating layer have an overlapping region having an area Sₐ, and a projection area of the first electrode on the transparent conductive layer is S₁, such that 0<Sₐ≤S_{1/2}.

5. The LED light-emitting unit according to claim 3, wherein the step is disposed around an edge of the first opening.

6. The LED light-emitting unit according to claim 1, further comprising:
a current blocking layer disposed on a bottom surface of the first opening.

7. The LED light-emitting unit according to claim 6, wherein the current blocking layer and the transparent conductive layer form a spacing groove, and the first electrode is embedded in the spacing groove to contact the second conductivity-type semiconductor layer.

8. The LED light-emitting unit according to claim 7, wherein a projection area of the current blocking layer on the transparent conductive layer is S₂, and a bottom surface area of the first opening is S₃, such that 0<S₂≤S_{3/2}.

9. The LED light-emitting unit according to claim 2, further comprising:
a refractive-index matching layer disposed on a surface of the second insulating layer opposite to the epitaxial stack to form a graded-index structure with the second insulating layer, the refractive-index matching layer having a refractive index not less than a refractive index of the second insulating layer.

10. The LED light-emitting unit according to claim 1, further comprising:
a reflective layer disposed on a surface of the substrate opposite to the epitaxial stack.

11. The LED light-emitting unit according to claim 2, wherein the second electrode comprises a second electrode pad disposed at a first end of the LED light-emitting unit, the first opening is formed at a second end of the LED light-emitting unit, and the first electrode comprises a first electrode pad and at least one electrode extension strip connected to the first electrode pad, and
wherein the first electrode pad extends through the first opening to contact the top surface of the first insulating layer, and the electrode extension strip extends from the first electrode pad toward the second end of the LED light-emitting unit.

12. The LED light-emitting unit according to claim 11, wherein at least a portion of the electrode extension strip is in contact with the transparent conductive layer, or
the electrode extension strip has a forked structure, and the forked structure contacts the transparent conductive layer by penetrating through the first insulating layer.

13. The LED light-emitting unit according to claim 1, wherein the first insulating layer has a via region comprising a plurality of vias.

14. The LED light-emitting unit according to claim 13, wherein the first insulating layer comprises:
a first region located below the first electrode; and
a second region comprising all regions of the first insulating layer other than the first region,
wherein the via region is located in the second region.

15. The LED light-emitting unit according to claim 13, wherein the via region is located above the light-emitting mesa.

16. The LED light-emitting unit according to claim 15, wherein a via of the plurality of vias exposes a portion of the surface of the transparent conductive layer.

17. The LED light-emitting unit according to claim 15, wherein at least one via of the plurality of vias extends downward from the first insulating layer to a surface of the second conductivity-type semiconductor layer.

18. The LED light-emitting unit according to claim 15, wherein the via region extends from above the light-emitting mesa to a sidewall of the light-emitting mesa.

19. A LED chip, comprising:
a plurality of LED light-emitting units isolated from one another by a plurality of trenches, wherein the LED light-emitting unit comprises:
a substrate;
an epitaxial stack disposed on a surface of the substrate, the epitaxial stack comprising, in sequence along a first direction, a first conductivity-type semiconductor layer, an active region, and a second conductivity-type semiconductor layer, wherein a local region of the epitaxial stack is etched down at least to the first conductivity-type semiconductor layer to form a recess and a light-emitting mesa, and wherein the first direction is perpendicular to the surface of the substrate and extends from the substrate toward the epitaxial stack;
a transparent conductive layer disposed on the light-emitting mesa and having a first opening exposing a portion of the second conductivity-type semiconductor layer;
a first insulating layer disposed on a surface of the transparent conductive layer opposite to the epitaxial stack; and
a first electrode extending through the first opening to contact a top surface of the first insulating layer.

20. A light-emitting device comprising a light-emitting diode employing the LED chip according to claim 19.
